(19) United States
(12) Patent Application Publication
(10) Pub. No.: US 2014/0015542 A1
(43) Pub. Date: Jan. 16, 2014

(54) MEASUREMENT CIRCUIT FOR LEAKAGE CURRENT OF CAPACITOR

(71) Applicants: YUN BAI, Shenzhen City (CN); PENG CHEN, Shenzhen City (CN); SONG-LIN TONG, Shenzhen City (CN)

(72) Inventors: YUN BAI, Shenzhen City (CN); PENG CHEN, Shenzhen City (CN); SONG-LIN TONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/598,863

(22) Filed: Aug. 30, 2012

(30) Foreign Application Priority Data
Jul. 16, 2012 (CN) 2012102449567

(51) Int. Cl. G01R 31/02

(52) U.S. Cl. 324/548

(57) ABSTRACT

A measurement circuit includes an instruction input unit, a charging circuit to charge a capacitor, a charging and discharging circuit to control the capacitor to leakage discharge, a control circuit, a first amplifying circuit, and a display unit. The control circuit receives a measurement instruction through the instruction input unit to control the charging circuit to charge the capacitor, and receives a stop charging signal from the charging circuit when a voltage of the capacitor reaches a saturation voltage for controlling the charging circuit to stop charging the capacitor. The first amplifying circuit measures a leakage voltage of the capacitor, amplifies the measured leakage voltage, and outputs the amplified leakage voltage to the control circuit. The display unit displays the leakage voltage of the capacitor.

### BACKGROUND

1. Technical Field

The present disclosure relates to measurement circuits, and particularly to a measurement circuit for measuring a leakage current of a capacitor.

2. Description of Related Art

At present, capacitors as energy storage, filtering, and decoupling components are widely used. Thus, capacitors are indispensable electronic components of electronic devices. Leakage current of a capacitor needs to be measured for assuring the quality of the capacitor. However, a general apparatus for measuring the leakage current of the capacitor is costly.

### BRIEF DESCRIPTION OF THE DRAWINGS

Many aspects of the embodiments can be better understood with reference to the following drawings. The components in the drawing are not necessarily drawn to scale, the emphasis instead being placed upon clearly illustrating the principles of the present embodiments.

FIG. 1 is a block diagram of a measurement circuit for leakage current of a capacitor in accordance with an exemplary embodiment of the present disclosure.

FIG. 2 to FIG. 6 are circuit diagrams of the measurement circuit of FIG. 1.

### DETAILED DESCRIPTION

The disclosure, including the drawing, is illustrated by way of example and not by way of limitation. References to “an” or “one” embodiment in this disclosure are not necessarily to the same embodiment, and such references mean at least one.

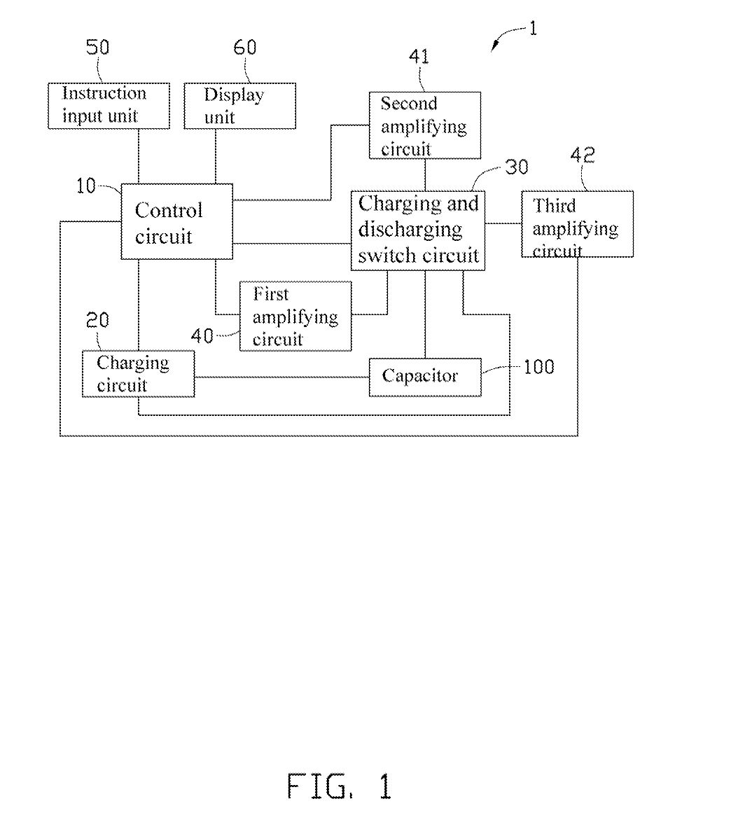

Referring to FIG. 1, an exemplary embodiment of a measurement circuit 1 is shown. The measurement circuit 1 is used for measuring a leakage current of a capacitor 100. The measurement circuit 1 includes a control circuit 10, a charging circuit 20, a charging and discharging switch circuit 30, first to third amplifying circuits 40-42, a display unit 60, and an instruction input unit 50. The control circuit 10 receives a measurement instruction through the instruction input unit 50 and controls the charging circuit 20 to charge the capacitor 100 through the charging and discharging switch circuit 30 according to the measurement instruction. The second amplifying circuit 41 measures a charging voltage of the capacitor 100 during charging through the charging and discharging switch circuit 30, amplifies the measured voltage, and outputs the amplified voltage to the control circuit 10. The control circuit 10 controls the charging circuit 20 to regulate a charging current for charging the capacitor 100 according to the received charging voltage. The charging circuit 20 measures a voltage of the capacitor 100 and outputs a stop charging signal to the control circuit 10 when the voltage of the capacitor 100 reaches a saturation voltage. The control circuit 10 controls the charging circuit 20 to stop charging the capacitor 100. The third amplifying circuit 42 measures the saturation voltage of the capacitor 100 through the charging and discharging switch circuit 30, amplifies the measured voltage and outputs the amplified voltage to the control circuit 10. The control circuit 10 controls the display unit 60 to display the saturation voltage. The control circuit 10 controls the capacitor 100 to leakage discharge through the charging and discharging switch circuit 30. The first amplifying circuit 40 measures a leakage voltage of the capacitor 100 through the charging and discharging switch circuit 30 during discharging, amplifies the measured voltage and outputs the amplified voltage to the control circuit 10. The control circuit 10 controls the display unit 60 to display the leakage voltage of the capacitor 100.

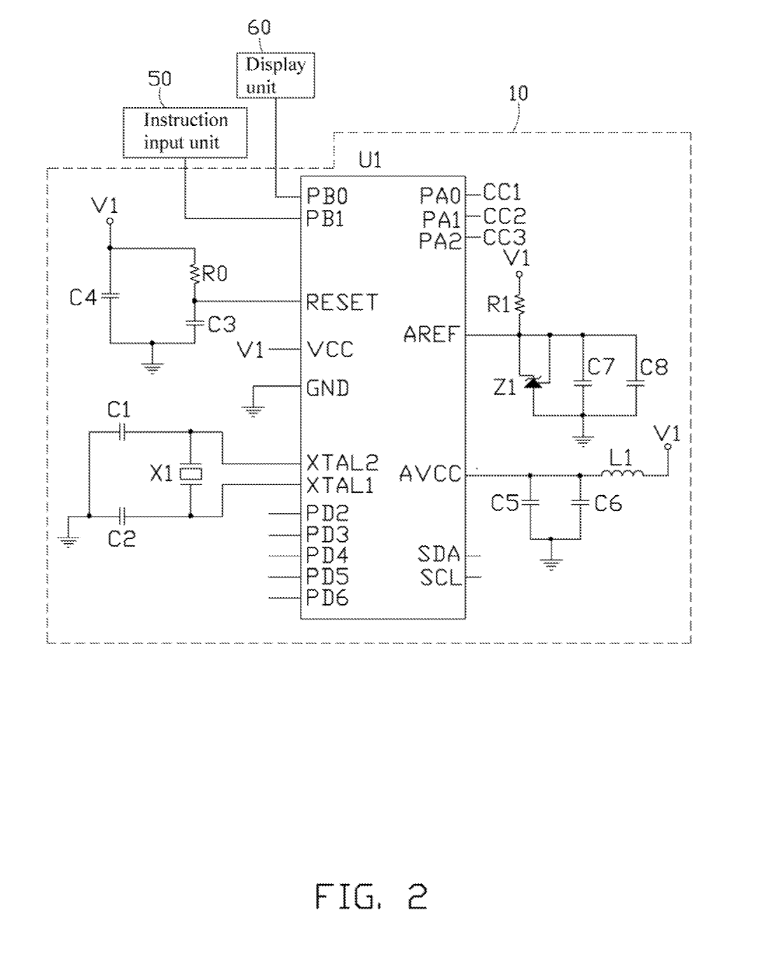

Referring to FIG. 2, an embodiment of the control circuit 10 is shown. The control circuit 10 includes a microcontroller U1, capacitors C1-C8, resistors R0 and R1, an inductor L1, a voltage regulating diode Z1, and a crystal oscillator X1. An input output (I/O) pin PB0 of the microcontroller U1 is connected to the display unit 60. An I/O pin PB1 of the microcontroller U1 is connected to the instruction input unit 50. A voltage pin VCC of the microcontroller U1 is connected to a power source V1. A ground pin GND of the microcontroller U1 is grounded. A reset pin RESET of the microcontroller U1 is connected to the power source V1 through the resistor R0 and also grounded through the capacitor C3. The capacitor C4 is connected between the power source V1 and ground. A clock pin XTAL1 of the microcontroller U1 is grounded through the capacitor C2. A clock pin XTAL2 of the microcontroller U1 is grounded through the capacitor C1. The crystal oscillator X1 is connected between the clock pins XTAL1 and XTAL2 of the microcontroller U1. I/O pins PD2, PD5, and PD6, a data pin SDA, and a clock pin SCL of the microcontroller U1 are all connected to the charging circuit 20. I/O pins PD3 and PD4 of the microcontroller U1 are connected to the charging and discharging switch circuit 30. I/O pins PA0, PA1, and PA2 of the microcontroller U1 are respectively connected to the first to third amplifying circuits 40-41. A reference pin AREF of the microcontroller U1 is connected to a cathode and a control terminal of the voltage regulating diode Z1 and also connected to the power source V1 through the resistor R1. An anode of the voltage regulating diode Z1 is grounded. The capacitors C7 and C8 are connected in parallel between the control terminal of the voltage regulating diode Z1 and ground. An analog voltage pin AVCC of the microcontroller U1 is connected to the power source V1 through the inductor L1. The capacitors C5 and C6 are connected in parallel between the analog voltage pin AVCC of the microcontroller U1 and ground.

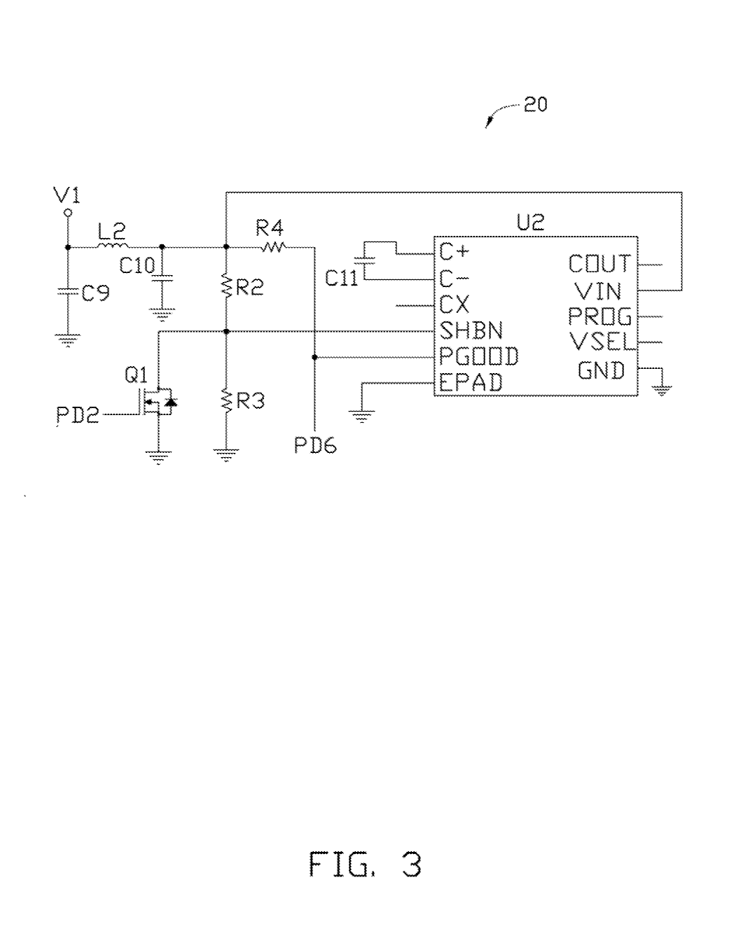

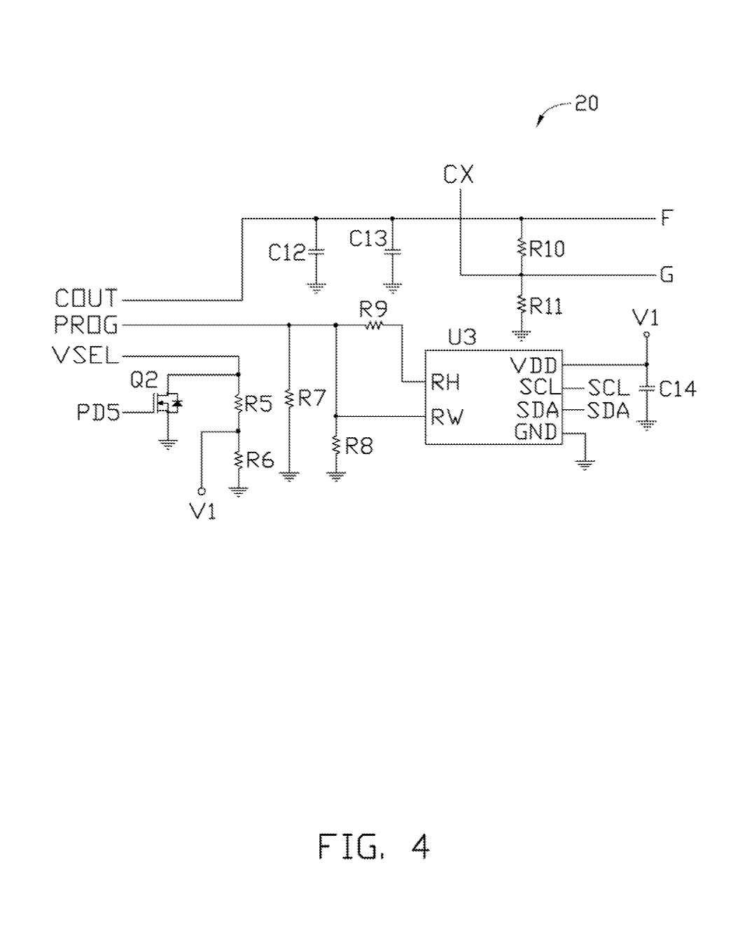

Referring to FIGS. 3 and 4, the charging circuit 20 includes capacitors C9-C14, a charging chip U2, a potentiometer U3, an inductor L2, resistors R2-R11, and field effect transistors (FETs) Q1 and Q2. The capacitor C11 is connected between I/O pins C+ and C− of the charging chip U2. An enable pin SHBN of the charging chip U2 is connected to a drain of the FET Q1 and also connected to the power source V1 through the resistor R2 and the inductor L2 in that order. The resistor R3 is connected between the drain of the FET Q1 and ground. A source of the FET Q1 is grounded. A gate of the FET Q1 is connected to the I/O pin PD2 of the microcontroller U1. The capacitor C9 is connected between the power source V1 and ground. The capacitor C10 is connected between a node between the resistor R2 and the inductor L2, and ground. An input pin VIN of the charging chip U2 is connected to the node between the resistor R2 and inductor L2. A control pin PGOOD of the charging chip U2 is connected to the I/O pin PD6 of the microcontroller U1 and also connected to the input pin VIN of the charging chip U2 through the resistor R4. A voltage regulating pin VSEL of the charging chip U2 is connected to a drain of the FET Q2 and also grounded through the resistors R5 and R6 in that order. The power source V1 is connected to a node between the resistors R5 and R6. A source of the FET Q2 is grounded. A gate of the FET Q2 is connected to the I/O pin PD5 of the microcontroller U1. A current regulating pin PROG of the charging chip U2 is connected to an I/O pin RH of the potentiometer U3 through the resistor R9. An I/O pin RW of the potentiometer U3 is connected to the current regulating pin PROG of the charging chip U2 and also grounded through the resistor R8. A voltage pin VDD of the potentiometer U3 is connected to the power source V1 and also grounded through the capacitor C14. A data pin SDA and a clock pin SCL of the potentiometer U3 are respectively connected to the data pin SDA and the clock pin SCL of the microcontroller U1. The resistor R7 is connected between the current regulating pin PGOG of the charging chip U2 and ground. A measuring pin COUT of the charging chip U2 is connected to a positive terminal of the capacitor 100 and also grounded through the resistors R10 and R11 in that order. The capacitors C12 and C13 are connected in parallel between the measuring pin COUT of the charging chip U2 and ground. A charging pin CX of the charging chip U2 is connected to a node between the resistors R10 and R11 and also connected to the charging and discharging switch circuit 30.

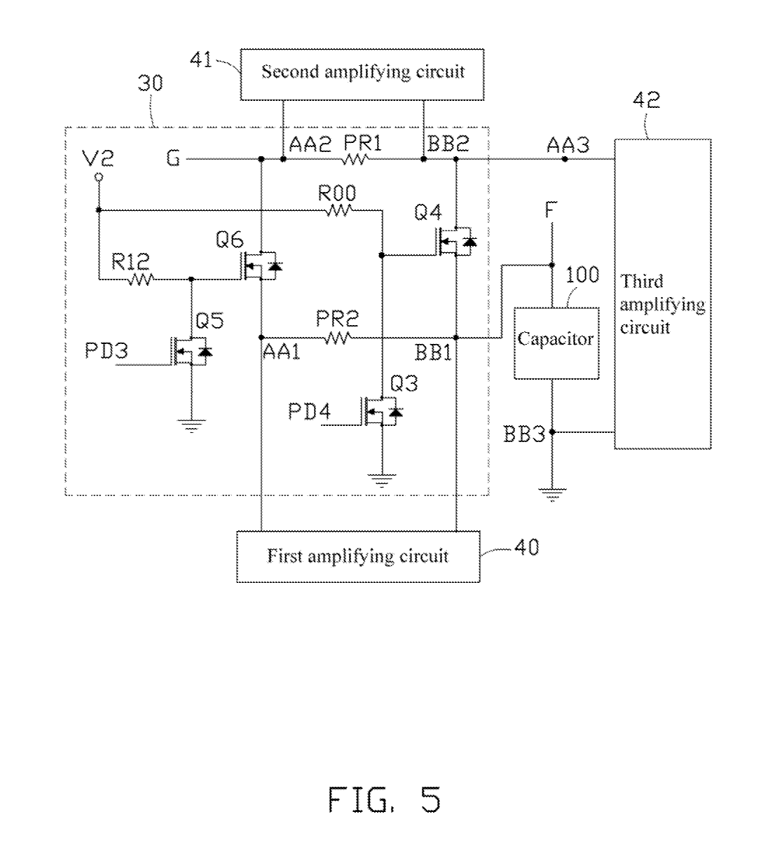

Referring to FIG. 5, the charging and discharging switch circuit 30 includes resistors R00 and R12, FETs Q3-Q6, and measuring resistors PR1 and PR2. A gate of the FET Q3 is connected to the I/O pin PD4 of the microcontroller U1. A source of the FET Q3 is grounded. A drain of the FET Q3 is connected to a gate of the FET Q4 and also connected to a power source V2 through the resistor R00. A source of the FET Q4 is connected to the positive terminal of the capacitor 100 and also connected to a source of the FET Q6 through the measuring resistor PR2. A negative terminal of the capacitor 100 is grounded. A drain of the FET Q4 is connected to the third amplifying circuit 42, and connected to a drain of the FET Q6 and the charging pin CX of the charging chip U2 through the measuring resistor PR1. A gate of the FET Q6 is connected to a drain of the FET Q5 and also connected to the power source V2 through the resistor R12. A gate of the FET Q5 is connected to the I/O pin PD3 of the microcontroller U1. A source of the FET Q5 is grounded. Two ends of the measuring resistor PR1 are connected to the first amplifying circuit 40. Two ends of the measuring resistor PR2 are connected to the second amplifying circuit 41.

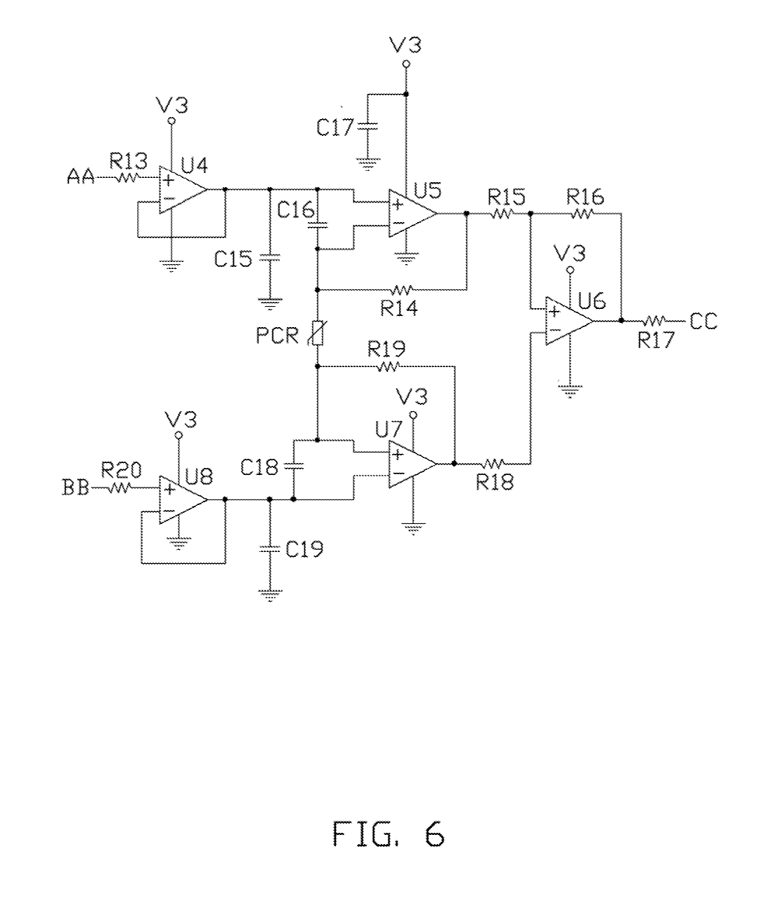

Referring to FIG. 6, each of the first to third amplifying circuits 40-42 includes two voltage input terminals AA and BB, a voltage output terminal CC, resistors R13-R20, amplifiers U4-U8, capacitors C15-C19, and a variable resistor PCR. In detail, the voltage input terminals of the first amplifying circuit 40 are AA1 and BB1. The voltage input terminals of the second amplifying circuit 41 are AA2 and BB2. The voltage input terminals of the third amplifying circuit 42 are AA3 and BB3. The voltage output terminals of the first to third amplifying circuits 40-42 are respectively CC1, CC2, and CC3. A non-inverting input terminal of the amplifier U4 is connected to the voltage input terminal AA through the resistor R13. An output terminal of the amplifier U4 is connected to an inverting input terminal of the amplifier U4 and a non-inverting input terminal of the amplifier U5. The capacitor C15 is connected between the output terminal of the amplifier U4 and ground. The capacitor C16 is connected between the non-inverting input terminal and an inverting input terminal of the amplifier U5. A voltage terminal of the amplifier U5 is connected to the power source V3 and also grounded through the capacitor C17. An output terminal of the amplifier U5 is connected to a non-inverting input terminal of the amplifier U6 through the resistor R15. The resistor R14 is connected between the inverting input terminal and the output terminal of the amplifier U5. An output terminal of the amplifier U6 is connected to the voltage output terminal CC through the resistor R17. The resistor R16 is connected between the non-inverting input terminal and the output terminal of the amplifier U6. A non-inverting input terminal of the amplifier U8 is connected to the voltage input terminal BB through the resistor R20. An output terminal of the amplifier U8 is connected to an inverting input terminal of the amplifier U8 and an inverting input terminal of the amplifier U7. The capacitor C18 is connected between a non-inverting input terminal and the inverting input terminal of the amplifier U7. The capacitor C19 is connected between the output terminal of the amplifier U8 and ground. The resistor R19 is connected between the non-inverting input terminal and the output terminal of the amplifier U7. The variable resistor PCR is connected between the inverting input terminal of the amplifier U5 and the non-inverting input terminal of the amplifier U7. The output terminal of the amplifier U7 is connected to an inverting input terminal of the amplifier U6 through the resistor R18. The voltage input terminals AA1 and BB1 of the first amplifying circuit 40 are connected to two ends of the measuring resistor PR2. The voltage output terminal CC1 of the first amplifying circuit 40 is connected to the I/O pin PA0 of the microcontroller U1. The voltage input terminals AA2 and BB2 of the second amplifying circuit 41 are connected to two ends of the measuring resistor PR1. The voltage output terminal CC2 of the second amplifying circuit 41 is connected to the I/O pin PA1 of the microcontroller U1. The voltage input terminal AA3 of the third amplifying circuit 42 is connected to the drain of the FET Q4. The voltage input terminal BB3 of the third amplifying circuit 42 is grounded. The voltage output terminal CC3 of the third amplifying circuit 42 is connected to the I/O pin PA2 of the microcontroller U1.

In use, the microcontroller U1 receives a measurement instruction through the instruction input unit 50 and outputs a high level signal to the FET Q1 through the I/O pin PD2 according to the received measurement instruction. The FET Q1 is turned on. The charging chip U2 operates. The microcontroller U1 outputs a high level signal or a low level signal to the FET Q2 through the I/O pin PD5, to control the FET Q2 to be turned on or turned off for regulating the charging voltage. The microcontroller U1 outputs a low level signal to the FET Q3 through the I/O pin PD4 to control the FET Q3 to be turned off. A gate of the FET Q4 receives a high level signal from the power source V2 and is turned on. The microcontroller U1 outputs a high level signal to the FET Q5 through the I/O pin PD3 to control the FET Q5 to be turned on. The drain of the FET Q5 outputs a low level signal to the gate of the FET Q6 for controlling the FET Q6 to be turned off. The charging chip U2 charges the capacitor 100 through the charging pin CX, the measuring resistor PR1, and the FET Q4. The second amplifying circuit 41 measures a voltage of the measuring resistor PR1, amplifies the measured voltage, and outputs the amplified voltage to the microcontroller U1. The microcontroller U1 controls the potentiometer U3 through the clock pin SCL and the data pin SDA to regulate a charging current charging the capacitor 100.

The charging chip U2 measures a voltage of the capacitor 100 through the measuring pin COUT and outputs a stop charging signal to the microcontroller U1 through the control pin PGOOD when the voltage of the capacitor 100 reaches the saturation voltage. The microcontroller U1 outputs a high level signal to the FET Q3 through the I/O pin PD4 according to the received stop charging signal. The FET Q3 is turned on. The drain of the FET Q3 outputs a low level signal to the FET Q4. The FET Q4 is turned off. The charging chip U2 does not output charging voltage to the capacitor 100 through the charging pin CX. Namely, the charging chip U2 does not charge the capacitor 100. The third amplifying circuit 42 amplifies the saturation voltage of the capacitor 100 and outputs the amplified saturation voltage to the microcontroller U1. The microcontroller U1 controls the display unit 60 to display the saturation voltage of the capacitor 100. The microcontroller U1 outputs a low level signal to the FET Q5 through the I/O pin PD3. The FET Q5 is turned off. The gate of the FET Q6 receives a high level signal from the power source V2 and is turned on. The capacitor 100 leakage discharges through the measuring resistor PR2. The first amplifying circuit 40 measures a leakage voltage of the measuring resistor PR2, amplifies the measured leakage voltage, and outputs the amplified leakage voltage to the microcontroller U1. The microcontroller U1 controls the display unit 60 to display the leakage voltage of the capacitor 100. The leakage current of the capacitor 100 can be gained through the leakage voltage of the capacitor 10 and the resistance of the measuring resistor PR2.

The measurement circuit 1 charges the capacitor 100 through the charging circuit 20, controls the capacitor 100 to leakage discharge through the charging and discharging switch circuit 30 when the voltage of the capacitor 100 reaches a saturation voltage, and measures the leakage voltage of the capacitor 100 through the first amplifying circuit 40, to gain the leakage current of the capacitor 100.

Even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A measurement circuit for measuring a leakage current of a capacitor, the measurement circuit comprising:
an instruction input unit;
a charging circuit to charge the capacitor;
a charging and discharging switch circuit to control the capacitor to leakage discharge;
a control circuit to receive a measurement instruction through the instruction input unit and control the charging circuit to charge the capacitor, receive a stop charging signal from the charging circuit when a voltage of the capacitor measured by the charging circuit reaches a saturation voltage, and control the charging circuit to stop charging the capacitor;
a first amplifying circuit to measure a leakage voltage of the capacitor when the charging and discharging switch circuit controls the capacitor to leakage discharge, amplify the measured leakage voltage, and output the amplified leakage voltage to the control circuit; and
a display unit to be controlled by the control circuit and display the leakage voltage of the capacitor, to gain a leakage current of the capacitor through the charging and discharging switch circuit.

2. The measurement circuit of claim 1, further comprising a second amplifying circuit, wherein the second amplifying circuit measures a charging voltage of the capacitor, amplifies the measured charging voltage, and outputs the amplified charging voltage to the control circuit, to signal the control circuit to control the charging circuit to regulate a charging current.

3. The measurement circuit of claim 2, further comprising a third amplifying circuit, wherein the third amplifying circuit measures a saturation voltage of the capacitor, amplifies the measured saturation voltage, and outputs the amplified saturation voltage to the control circuit, to signal the control circuit to control the display unit to display the saturation voltage of the capacitor.

4. The measurement circuit of claim 3, wherein the control circuit comprises a microcontroller, first to eighth capacitors, first and second resistors, a first inductor, a voltage regulating diode, and a crystal oscillator, a first input output (I/O) pin of the microcontroller is connected to the display unit, a second I/O pin of the microcontroller is connected to the instruction input unit, a voltage pin of the microcontroller is connected to a first power source, a reset pin of the microcontroller is connected to the first power source through the first resistor and also grounded through the third capacitor, the fourth capacitor is connected between the first power source and ground, a first clock pin of the microcontroller is grounded through the second capacitor, a second clock pin of the microcontroller is grounded through the first capacitor, the crystal oscillator is connected between the first and second clock pins of the microcontroller, a third I/O pin, a sixth I/O pin, a seventh I/O pin, a data pin, and a clock pin of the microcontroller are all connected to the charging circuit, fourth and fifth I/O pins of the microcontroller are connected to the charging and discharging switch circuit, eighth to tenth I/O pins of the microcontroller are respectively connected to the first to third amplifying circuits, a reference pin of the microcontroller is connected to a cathode and a control terminal of the voltage regulating diode, the reference pin of the microcontroller is also connected to the first power source through the second resistor, an anode of the voltage regulating diode is grounded, the seventh and eighth capacitors are connected in parallel between the control terminal of the voltage regulating diode and ground, an analog voltage pin of the microcontroller is connected to the first power source through the first inductor, the fifth and sixth capacitors are connected in parallel between the analog voltage pin of the microcontroller and ground.

5. The measurement circuit of claim 4, wherein the charging circuit comprises ninth to fourteenth capacitors, a charging chip, a potentiometer, a second inductor, third to twelfth resistors, and first and second field effect transistors (FETs), the eleventh capacitor is connected between first and second I/O pins of the charging chip, an enable pin of the charging chip is connected to a drain of the first FET and also connected to a first end of the second inductor through the third resistor, a second end of the second inductor is connected to the first power source, the fourth resistor is connected to the drain of the first FET and ground, a source of the FET is grounded, a gate of the first FET is connected to the third I/O pin of the microcontroller, the ninth capacitor is connected between the second end of the second inductor and ground, the tenth capacitor is connected between the first end of the second inductor and ground, an input pin of the charging chip is connected between a node between the third resistor and the second inductor, and ground, a control pin of the charging chip is connected to the seventh I/O pin of the microcontroller and also connected to the input pin of the charging chip through the fifth resistor, a voltage regulating pin of the charging chip is connected to a drain of the second FET and also grounded through the sixth and seventh resistors in that order, the first power source is connected to a node between the sixth and seventh resistors, a source of the second FET is grounded, a gate of the second FET is connected to the sixth I/O pin of the microcontroller, a current regulating pin of the charging chip is connected to a first I/O pin of the potentiometer through the tenth resistor, a second I/O pin of the potentiometer is connected to the current regulating pin of the charging chip and also grounded through the ninth resistor, a voltage pin of the potentiometer is connected to the first power source and also grounded through the fourteenth capacitor, a data pin and a clock pin of the potentiometer are connected to the data pin and the clock pin of the microcontroller, the eighth resistor is connected between the current regulating pin of the charging chip and ground, a measuring pin of the charging chip is connected to a positive terminal of the capacitor and also grounded through the eleventh and twelfth resistors in that order, a negative terminal of the capacitor is grounded, the twelfth and thirteenth capacitors are connected in parallel between the measuring pin of the charging chip and ground, a charging pin of the charging chip is connected to a node between the eleventh and twelfth resistors and also connected to the charging and discharging switch circuit.

6. The measurement circuit of claim 5, wherein the charging and discharging switch circuit comprises thirteenth and fourteenth resistors, third to sixth FETs, and first and second measuring resistors, a gate of the third FET is connected to the fifth I/O pin of the microcontroller, a source of the third FET is grounded, a drain of the third FET is connected to a gate of the fourth FET and also connected to a second power source through the thirteenth resistor, a source of the fourth FET is connected to the positive terminal of the capacitor and also connected to a source of the sixth FET through the second measuring resistor, a drain of the fourth FET is connected to the third amplifying circuit and also connected to a drain of the sixth FET and the charging pin of the charging chip through the first measuring resistor, a gate of the sixth FET is connected to a drain of the fifth FET and also connected to the second power source through the fourteenth resistor, a gate of the fifth FET is connected to the fourth I/O pin of the microcontroller, a source of the fifth FET is grounded, two ends of the first measuring resistor are connected to the second amplifying circuit, two ends of the second measuring resistor are connected to the first amplifying circuit.

7. The measurement circuit of claim 6, wherein each of the first to third amplifying circuits comprises first and second voltage input terminals, a voltage output terminal, fifteenth to twenty-second resistors, first to fifth amplifiers, fifteenth to nineteenth capacitors, and a variable resistor, a non-inverting input terminal of the first amplifier is connected to the first input terminal through the fifteen resistor, an output terminal of the first amplifier is connected to the non-inverting input terminal of the first amplifier and a non-inverting input terminal of the second amplifier, the fifteen capacitor is connected to the output terminal of the first amplifier and ground, the sixteenth capacitor is connected to the non-inverting input terminal and an inverting input terminal of the second amplifier, a voltage terminal of the second amplifier is connected to a third power source and also grounded through the seventeenth capacitor, an output terminal of the second amplifier is connected to a non-inverting input terminal of the third amplifier through the seventeenth resistor, the sixteenth resistor is connected between the non-inverting input terminal and the output terminal of the second amplifier, an output terminal of the third amplifier is connected to the voltage output terminal through the seventeenth resistor, the eighteenth resistor is connected between the non-inverting input terminal and the output terminal of the third amplifier, a non-inverting input terminal of the fourth amplifier is connected to the second voltage input terminal through the twenty-second resistor, an output terminal of the fourth amplifier is connected to an inverting input terminal of the fourth amplifier and an inverting input terminal of the fifth amplifier, the eighteenth capacitor is connected between the non-inverting input terminal and the inverting input terminal of the fifth amplifier, the nineteenth capacitor is connected between the output terminal of the fourth amplifier and ground, the twenty-first resistor is connected between the non-inverting input terminal and output terminal of the fifth amplifier, the variable resistor is connected between the inverting terminal of the fifth amplifier and the non-inverting terminal of the seventh amplifier, an output terminal of the fifth amplifier is connected to the inverting input terminal of the third amplifier through the twelfth resistor, the first and second voltage input terminals of the first amplifying circuit are connected to two ends of the second measuring resistor, the voltage output terminal of the first amplifying circuit is connected to the eighth I/O pin of the microcontroller, the first and second voltage input terminals of the second amplifying circuit are connected to two ends of the first measuring resistor, the voltage output terminal of the second amplifying circuit is connected to the ninth I/O pin of the microcontroller, the first voltage input terminal of the third amplifying circuit is connected to the drain of the fourth FET, the second voltage input terminal of the third amplifying circuit is grounded, the voltage output terminal of the third amplifying circuit is connected to the tenth I/O pin of the microcontroller.
